(19) United States
(12) Patent Application Publication
(10) Pub. No.: US 2020/0243634 A1
(43) Pub. Date: Jul. 30, 2020

(54) DISPLAY SUBSTRATE AND METHOD OF MANUFACTURING THE SAME, DISPLAY PANEL, AND DISPLAY DEVICE

(71) Applicants: Ordos Yuansheng Optoelectronics Co., Ltd., Inner Mongolia (CN); BOE TECHNOLOGY GROUP CO., LTD., Beijing (CN)

(72) Inventor: Zhibo Wen, Beijing (CN)

(21) Appl. No.: 16/608,323

(22) PCT Filed: May 6, 2019
(86) PCT No.: PCT/CN2019/085684

§ 371 Date: Oct. 25, 2019

(30) Foreign Application Priority Data
May 9, 2018 (CN) 201810436996.9

(51) Int. Cl. H01L 27/32; H01L 51/56

(52) U.S. Cl. CPC H01L 27/3272; H01L 51/56; H01L 27/3248

(57) ABSTRACT

The present disclosure provides a display substrate, a method of manufacturing the same, a display panel, and a display device. The display substrate includes a base substrate, a gate layer, a gate insulating layer, a source and drain layer, and a shielding layer; the gate layer, the gate insulating layer, the source and drain layer, and the shielding layer are arranged sequentially in a direction away from the base substrate; a side of the shielding layer that faces away from the base substrate has a protrusion, and an orthographic projection of the protrusion on the base substrate overlaps with a target orthographic projection; the target orthographic projection includes: a portion of the orthographic projection of the gate layer on the base substrate that overlaps with an orthographic projection of the source and drain layer on the base substrate.

### CROSS-REFERENCE TO RELATED APPLICATION

The present application is a Section 371 National Stage Application of International Application No. PCT/CN2019/085684, filed on May 6, 2019, entitled “Display substrate and method of manufacturing the same, display panel and display device”, which claims the benefit of Chinese Patent Application No. 201810436996.9 filed on May 9, 2018 with the China National Intellectual Property Administration and entitled with “Display panel and method of manufacturing the same, and display device”, the whole disclosure of which is incorporated herein by reference.

### TECHNICAL FIELD

The present disclosure relates to the field of display technologies, and in particular to a display substrate, a method of manufacturing the same, a display panel, and a display device.

### BACKGROUND

An OLED (organic light-emitting diode) display panel has gradually become popular in the display field due to its properties such as self-illumination, light-weight, small thinness, wide viewing angle, high brightness and high contrast. The OLED display panel is widely used in terminal products such as smartphones, tablets, and televisions.

As is known to the inventors, in the manufacturing of the OLED display panel, its encapsulation is completed by sealing and bonding a base substrate which the gate layer, the gate insulating layer and the source and drain layer are provided on, and a cover plate directly using encapsulant, thereby preventing external pollutants, moisture and the oxygen from entering the display panel and causing damage to the same.

### SUMMARY

Embodiments of the present disclosure provides a display substrate which includes: a base substrate, a gate layer, a gate insulating layer, a source and drain layer, and a shielding layer;

the gate layer, the gate insulating layer, the source and drain layer, and the shielding layer are arranged sequentially in a direction away from the base substrate;

wherein, a side of the shielding layer that faces away from the base substrate has a protrusion, and an orthographic projection of the protrusion on the base substrate overlaps with a target orthographic projection; and the target orthographic projection includes: a portion of an orthographic projection of the gate layer on the base substrate that overlaps with an orthographic projection of the source and drain layer on the base substrate.

In some embodiments, a surface of the protrusion that faces away from the base substrate includes a convex surface.

In some embodiments, the convex surface includes a curved convex surface.

In some embodiments, a generatrix of the curved convex surface has a semicircle shape.

In some embodiments, the protrusion has one or more side surfaces which connect a surface of the protrusion that faces towards the base substrate with a surface of the protrusion that faces away from the base substrate, and the one or more side surfaces of the protrusion include a concave surface.

In some embodiments, the concave surface includes a curved concave surface.

In some embodiments, a surface of the protrusion that faces away from the base substrate and a surface of the protrusion that faces towards the base substrate have one or more shared edges.

In some embodiments, the surface of the protrusion that faces away from the base substrate and the surface of the protrusion that faces towards the base substrate have two shared edges which extend in the same direction.

In some embodiments, the protrusion is strip-shaped, and a lengthwise direction of the protrusion is parallel to the base substrate.

In some embodiments, a width of an orthographic projection of the protrusion on the base substrate is greater than or equal to 2.4 μm.

In some embodiments, a material of the protrusion includes photoresist.

In some embodiments, the shielding layer includes a plurality of the protrusions, and there is a space between orthographic projections of any two adjacent protrusions on the base substrate.

In some embodiments, a minimum distance between any two adjacent protrusions is greater than or equal to a distance threshold, where the distance threshold is in a ranged between 2 μm and 3 μm.

In some embodiments, the shielding layer includes a pad layer and the protrusion;

the protrusion is arranged at a side of the pad layer away from the base substrate, and the orthographic projection of the protrusion on the base substrate is located within an orthographic projection of the pad layer on the base substrate and is different from the orthographic projection of the pad layer on the base substrate.

In some embodiments, an orthographic projection of the gate layer on the base substrate is located within an orthographic projection of all the protrusion in the shielding layer on the base substrate.

In some embodiments, the shielding layer includes a plurality of the protrusions, and the gate layer includes a plurality of gate patterns;

there is a space between orthographic projections of any two adjacent protrusions on the base substrate, and an orthographic projection of each of the gate patterns on the base substrate is located within an orthographic projection of its corresponding protrusion on the base substrate.

In some embodiments, the gate layer includes a plurality of gate patterns, and the display substrate further includes a spacer insulating layer;

some of the plurality of gate patterns are located on a side of the spacer insulating layer that faces towards the base substrate, while others of the plurality of gate pattern are located on a side of the spacer insulating layer that faces away from the base substrate.

Embodiments of the present disclosure also provide a display panel. The display panel includes: a cover plate, encapsulant, and the display substrate as described above, wherein a side of the display substrate on which the shielding layer is located is bonded to the cover plate by the encapsulant.

Embodiments of the present disclosure also provide a display device including the display panel as described above.

Embodiments of the present disclosure also provide a method of manufacturing a display substrate, the method including:

forming a gate layer, a gate insulating layer, and a source and drain layer on a base substrate sequentially; and

forming a shielding layer on the base substrate on which the source and drain layer is formed;

wherein, a side of the shielding layer that faces away from the base substrate has a protrusion, and an orthographic projection of the protrusion on the base substrate overlaps with a target orthographic projection; the target orthographic projection includes: a portion of an orthographic projection of the gate layer on the base substrate that overlaps with an orthographic projection of the source and drain layer on the base substrate.

In some embodiments, the step of forming a shielding layer on the base substrate on which the source and drain layer is formed includes:

forming a photoresist layer on the base substrate on which the source and drain layer is formed; and

sequentially performing an exposure process, a development process, and a curing process on the photoresist layer to form a shielding layer.

In some embodiments, the step of performing the exposure process, the development process, and the curing process on the photoresist layer includes:

exposing the photoresist layer with a mask; wherein the mask has fully transparent regions and opaque regions; or the mask has fully transparent regions, semi-transparent regions, and opaque regions; and

developing and curing the exposed photoresist layer sequentially.

### BRIEF DESCRIPTION OF THE DRAWINGS

FIG. 1 is a schematic view showing a structure of a display substrate according to an embodiment of the present disclosure;

FIG. 2 is a schematic view showing a structure of another display substrate according to an embodiment of the present disclosure;

FIG. 3 is a schematic view showing a structure of another display substrate according to an embodiment of the present disclosure;

FIG. 4 is a schematic view showing a structure of another display substrate according to an embodiment of the present disclosure;

FIG. 5 is a schematic view showing a structure of another display substrate according to an embodiment of the present disclosure;

FIG. 6 is a top view showing a display substrate according to an embodiment of the present disclosure;

FIG. 7 is a bottom view showing a display panel according to an embodiment of the present disclosure;

FIG. 8 is a schematic view showing a structure of another display substrate according to an embodiment of the present disclosure;

FIG. 9 is a schematic view showing a structure of another display substrate according to an embodiment of the present disclosure;

FIG. 10 is a schematic view showing a display substrate and a cover plate bonded together according to an embodiment of the present disclosure;

FIG. 11 is a schematic view showing a structure of another display substrate according to an embodiment of the present disclosure;

FIG. 12 is a schematic view showing a structure of a display panel according to an embodiment of the present disclosure;

FIG. 13 is a flowchart of a method of manufacturing a display substrate according to an embodiment of the present disclosure;

FIG. 14 is a flowchart of a method of manufacturing another display substrate according to an embodiment of the present disclosure;

FIG. 15 is a schematic view showing the process of manufacturing a display substrate according to an embodiment of the present disclosure;

FIG. 16 is a flowchart of a method of forming a shielding layer according to an embodiment of the present disclosure;

FIG. 17 is a flowchart of another method of forming a shielding layer according to an embodiment of the present disclosure;

FIG. 18 is a schematic view showing the thickness of a mask according to an embodiment of the present disclosure; and

FIG. 19 is a schematic view showing the thickness of another mask according to an embodiment of the present disclosure.

### DETAILED DESCRIPTION OF EMBODIMENTS

In order to make the principle, technical solutions and advantages of the present disclosure clearer, the present disclosure will be further described in detail below with reference to the accompanying drawings. It is obvious that the described embodiments are only part of the embodiments of the present disclosure, rather than all of the embodiments. Based on the described embodiments herein, those skilled in the art can obtain other embodiment(s), without any inventive efforts, which should fall within the scope of the present disclosure.

As known to the inventors, the display panel is obtained by encapsulating a display substrate and a cover plate through encapsulant usually. During the process of encapsulating the display substrate and the cover plate, the ground encapsulant is coated on the cover plate firstly, and then the cover plate coated with the encapsulant is bonded to the display substrate in a vacuum environment. Then, the display substrate and cover plate bonded together are placed in an atmosphere, and the encapsulant between the display substrate and the cover plate is irradiated by a laser and thus cured.

However, it is likely to produce foreign particles in the encapsulant (such as frit) if it is ground unevenly or when it is irradiated by laser light. When the display substrate and cover plate bonded together are placed in the atmosphere, a vacuum environment is formed between the display substrate and the cover plate. If foreign particles are present in the encapsulant, they will penetrate the source and drain layer, the gate insulating layer and the gate layer under the influence of the pressure difference between the atmosphere and the vacuum environment and the gravity of the cover plate, and thus the source and drain layer and the gate layer are shorted so that dark lines are present on the display panel when images are displayed. Embodiments of the present disclosure provide a display substrate. For the display panel employing this display substrate, it is unlikely to show dark lines when images are displayed on the display panel.

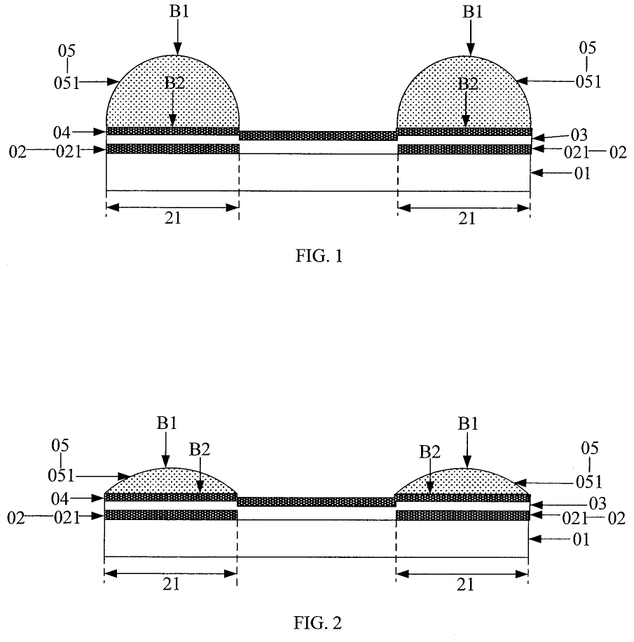

As an example, FIG. 1 is a schematic view showing a structure of a display substrate according to an embodiment of the present disclosure. As shown in FIG. 1, the display panel includes a base substrate 01, a gate layer 02, a gate insulating layer 03, a source and drain layer 04 and a shielding layer 05. The gate layer 02, the gate insulating layer 03, the source and drain layer 04, and the shielding layer 05 may be arranged sequentially in the direction away from the base substrate 01. The side of the shielding layer 05 that faces away from the base substrate 01 has a protrusion 051. The orthographic projection of the protrusion 051 on the base substrate 01 overlaps with a target orthographic projection 21. The target orthographic projection 21 includes: a portion of the orthographic projection of the gate layer 02 on the base substrate 01 that overlaps with the orthographic projection of the source and drain layer 04 on the base substrate 01.

It should be noted that, as an example, the orthographic projection of the protrusion 051 in FIG. 1 on the base substrate 01 and the target orthographic projection 21 are overlapped fully with each other. Alternatively, the orthographic projection of the protrusion 051 on the base substrate 01 and the target orthographic projection 21 may be overlapped partially with each other. The shielding layer 05 may have one protrusion 051 or a plurality of protrusions 051. As an example in FIG. 1, the shielding layer 05 has a plurality of protrusions 051 and there is a space between the orthographic projections of any two adjacent protrusions 051 on the base substrate 01. In addition, the source and drain layer 04 includes at least a source pattern and a drain pattern (not shown in FIG. 1), and the display panel further includes an active layer (not shown in FIG. 1).

In some embodiments, the material of the protrusion 051 may be electrically insulating material or electrically conductive material. The electrically insulating material may include photoresist (such as an ultraviolet positive photoresist or an ultraviolet negative photoresist). The electrically conductive material may be the same as or different from the material of the source and drain layer, which is not limited in the embodiments of the present disclosure. The material of the gate layer 02 and the material of the source and drain layer 04 may be metal or non-metal (such as indium tin oxide, indium zinc oxide, etc.).

As known to the inventors, in the case where the foreign particles are present in the encapsulant, it is likely for the source and drain layer and the gate layer to be pressed and penetrated by the foreign particles and thus be shorted. In the embodiment of the present disclosure, the side of the shielding layer that faces away from the base substrate has protrusions, and the orthographic projection of the protrusions on the base substrate overlaps with the target orthographic projection (the orthographic projection of the intersection of the gate layer with the source and drain layer on the base substrate). As a result, the portion of the gate pattern that overlaps with the source and drain layer is covered by the protrusion. During the process of encapsulating the display substrate and the cover plate by the encapsulant, if the foreign matter particles in the encapsulant are located on the protrusion, the foreign particles may slide off the protrusion under the influence of the air pressure difference between the atmospheric environment and the vacuum environment and the gravity of the cover plate. Therefore, foreign matter particles can be prevented from staying at the intersection of the source and drain layer and the gate layer, thereby preventing foreign matter particles from being pressed to penetrate the source and drain layer and the gate layer.

In summary, in the display substrate provided by the embodiment of the present disclosure, the side of the shielding layer that faces away from the base substrate has protrusions, and the orthographic projection of the protrusions on the base substrate overlaps with the target orthographic projection. When the display substrate and the cover plate are bonded by the encapsulant, it is difficult for the foreign particles in the encapsulant to stay on the protrusion, so it is difficult for the foreign particles to be pressed to penetrate the intersection of the source and drain layer and the gate layer. Therefore, the probability of short-circuiting between the source and drain layer and the gate layer can be reduced, thereby reducing the probability of dark lines appearing on the display panel during displaying images, and improving the quality of the display panel.

In the embodiment of the present disclosure, the surface of the protrusion can be shaped such that it is easier for objects to slide off the surface of the protrusion, as a result it is difficult for the foreign matter particles to stay on the protrusion 051, thereby preventing the foreign matter particles from being pressed to penetrate the intersection of the source and drain layer and the gate layer. The shape of the surface of the protrusion will be explained in detail below.

In a first aspect, referring to FIG. 1, the surface B1 of the protrusion 051 that faces away from the base substrate 01 may include a convex surface. In this case, if the foreign matter particles are attached to the protrusion 051, the foreign matter particles tend to slide off from the convex surface of the protrusion 051, so that it is difficult for the foreign matter particles to stay on the protrusion 051. Alternatively, the surface B1 of the protrusion 051 that faces away from the base substrate 01 may not be a convex surface. For example, the surface B1 may be a planar surface in parallel with the base substrate 01, or a planar surface having an angle with the base substrate 01, which is not limited in the embodiments of the present disclosure.

When the surface B1 is a convex surface, the convex surface may be a curved convex surface or a bend convex surface. When the surface B1 is a curved surface, the foreign matter particles would be easier to slide off from the convex surface of the protrusion 051, thereby further increasing the difficulty of the foreign matter particles staying on the protrusion 051. As shown in FIG. 1, the generatrix of the curved convex surface may have a semicircle shape. Alternatively, the generatrix of the curved convex surface may have a shape other than the semicircle shape, such as an arc shape as shown in FIG. 2, which is not limited in the embodiment of the present disclosure.

In the second aspect, the surface B1 of the protrusion 051 that faces away from the base substrate 01 and the surface B2 of the protrusion 051 that faces towards the base substrate 01 may have one or more shared edge. When the surface B1 and the surface B2 of the protrusion have a shared edge, the surface B1 and the surface B2 are connected, and the foreign matter particles on the protrusion would be easier to slide off from the convex surface of the protrusion 051. For example, as an example in FIG. 1, the surface B1 of the protrusion 051 that faces away from the base substrate 01 and the surface B2 of the protrusion 051 that faces towards the base substrate 01 have two shared edges which extend in the same direction. Moreover, when the surface B1 of the protrusion 051 is a curved convex surface, the two edges formed by the continuous movement of the two ends of the generatrix of the curved convex surface may be the same as the two edges of the surface B2 of the protrusion 051. Additionally, when the generatrix has a semicircle shape, the cross section of the protrusion 051 (such as the cross section shown in FIG. 1) may be semicircular.

In the third aspect, as an example, the surface B1 of the protrusion 051 that faces away from the base substrate 01 and the surface B2 of the protrusion 051 that faces to the base substrate 01 have two shared edges. Alternatively, any one of the surface B1 of the protrusion 051 that faces away from the base substrate 01 and the surface B2 of the protrusion 051 that faces towards the base substrate 01 may have at least one edge that is not shared by the other of them. In this case, the protrusion 051 has a side surface which connects the surface B1 of the protrusion 051 that faces away from the base substrate 01 with the surface B2 of the protrusion 051 that faces towards the base substrate 01.

As shown in FIG. 3, one or more side surface B3 of the protrusion 051 may be concave surface (in FIG. 3, a plurality of side surfaces B3 are illustrated as an example, in which case the protrusion 051 has a mountain-like shape). Under the influence of the concave surface, the foreign matter particles would be easier to slide off between the protrusions, thereby preventing the foreign matter particles from staying on the surface B1 of the protrusion 051 that faces away from the base substrate 01. Further, the concave surface may include a curved concave surface that enables the foreign matter particles to slide off easily between the protrusions.

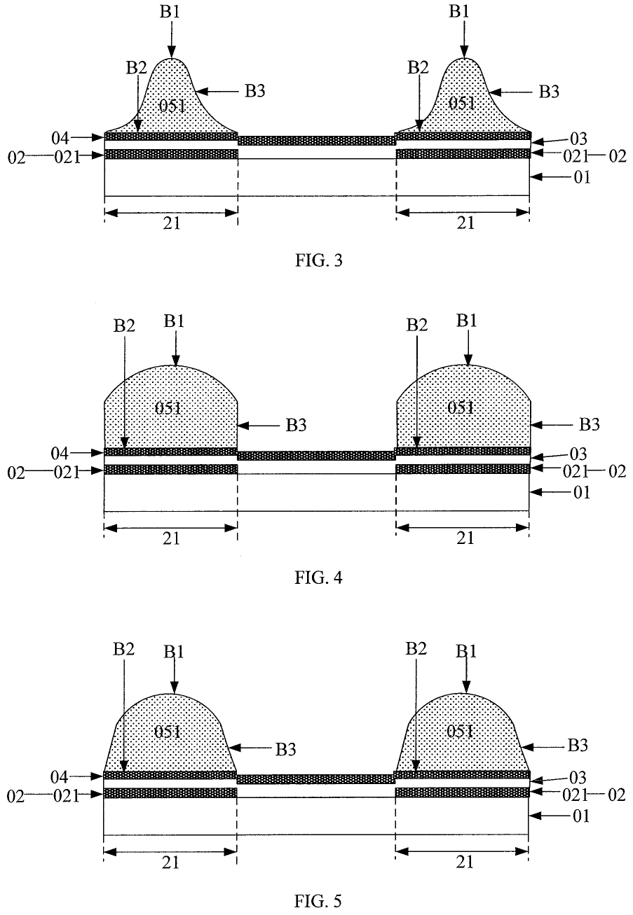

Alternatively, the concave surface may not be a curved concave surface. For example, the concave surface may be a bend concave surface. The above-mentioned side surface B3 may not be a concave surface, but for example a planar surface, which is not limited by the embodiment of the present disclosure. Additionally, when the side surface B3 is a planar surface, the side surface B3 may be perpendicular to the base substrate 01 (as shown in FIG. 4) or inclined to the base substrate 01 (as shown in FIG. 5). In some embodiments, one end of the side surface B3 in FIG. 5 that is close the base substrate 01 may be inclined outward along the protrusion, which may facilitate the sliding of the foreign matter particles from the protrusion 051.

Referring to FIG. 1, on the basis that the orthographic projection of the protrusion 051 on the base substrate 01 overlaps with the target orthographic projection 21, the orthographic projection of the gate layer 02 on the base substrate 01 may be located within the orthographic projection of all the protrusions 051 in shielding layer 05 on the base substrate 01. In this way, any positions in the gate layer 02 can be prevented from being penetrated by the foreign particles.

For example, the gate layer 02 may include a plurality of gate patterns 021 in one-to-one correspondence with the plurality of protrusions 051, and the orthographic projection of each of the gate patterns 021 on the base substrate 01 may be located within the orthographic projection of its corresponding protrusion 051 on the base substrate 01.

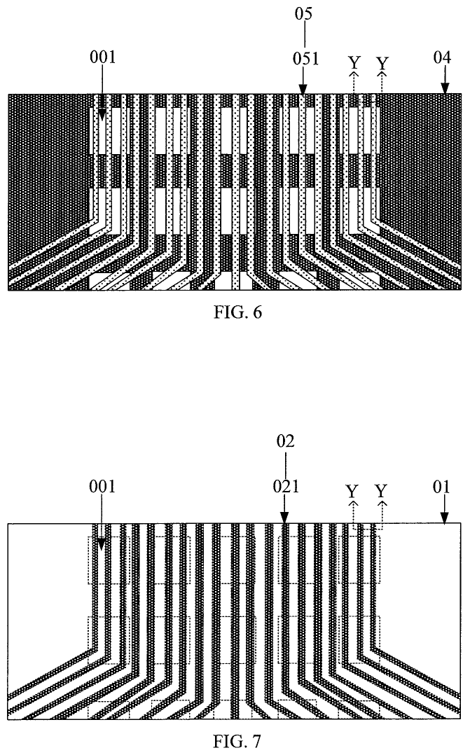

FIG. 6 is a top view showing a partial structure of the display substrate of FIG. 1 according to an embodiment of the present disclosure, and FIG. 1 is a schematic view showing a section along line YY of FIG. 6. FIG. 7 is a bottom view showing a partial structure of the display substrate of FIG. 1 according to an embodiment of the present disclosure, and FIG. 1 is a schematic view showing a section along line YY of FIG. 7. Referring to FIG. 6 and FIG. 7, the orthographic projections of the gate pattern 021 and the protrusion 051 on the base substrate may be strip-shaped, and the lengthwise directions of the gate pattern 021 and the protrusion 051 are both parallel to the base substrate 01. The width of the orthographic projection of each gate pattern 021 on the base substrate 01 may be less than or equal to the width of the orthographic projection of its corresponding protrusion 051 on the base substrate 01. Therefore, the size of the protrusion 05 may be determined according to the size of the area of the orthographic projection of the gate pattern on the base substrate. For example, when the area of the orthographic projection of the gate pattern on the base substrate is relatively large, a relatively large protrusion may be provided; when the area of the orthographic projection of the gate pattern on the base substrate is relatively small, a relatively small protrusion may be provided. The size of the protrusion is not limited in the embodiment of the present disclosure.

For example, the width of the orthographic projection of each gate pattern 021 on the base substrate 01 may be 2.4 μm. In this case, the width of the orthographic projection of each protrusion 051 on the base substrate 01 may be greater than or equal to 2.4 μm. (e.g. equal to 2.4 μm or 3 μm, etc.). The maximum thickness of the protrusion 051 in a direction perpendicular to the base substrate 01 may be 1.2 μm, and the minimum distance between any two adjacent protrusions 051 is 3 μm.

As another example, the width of the orthographic projection of each gate pattern 021 on the base substrate 01 may be 5.6 μm. In this case, the width of the orthographic projection of each protrusion 051 on the base substrate 01 may be greater than or equal to 5.6 μm. (e.g. equal to 5.6 μm or 6 μm, etc.). The maximum thickness of the protrusion 051 in a direction perpendicular to the base substrate 01 may be 2.6 μm, the thickness of the source and drain layer 04 may be 0.7 μm, the thickness of the gate layer 02 may be 0.3 μm, and the minimum distance between any two adjacent protrusions 051 is 7 μm.

In some embodiments, the orthographic projection of each gate pattern 021 on the base substrate 01 may also be located within the orthographic projection of the plurality of protrusions 051 on the base substrate 01; the orthographic projection of each protrusions 051 on the base substrate 01 may cover the orthographic projection of at least two gate patterns 021 on the base substrate 01; the orthographic projection of the gate layer 02 on the base substrate 01 may also be only partially located within the orthographic projection of all the protrusions 051 in the shielding layer 05 on the base substrate 01, which is not limited in the embodiment of the present disclosure.

In addition, the source and drain layer may have hollowed-out areas (such as the hollowed-out area 001 shown in FIG. 6 or FIG. 7). The region where the hollowed-out area 001 is located may not be covered by the protrusion 051. In the embodiment of the present disclosure, as an example, the region where the hollowed-out area 001 is located is also covered by the protrusion 051.

In the embodiments mentioned above, as an example, the shielding layer 05 includes the protrusions 051 only. Alternatively, the shielding layer 05 may further include a pad layer.

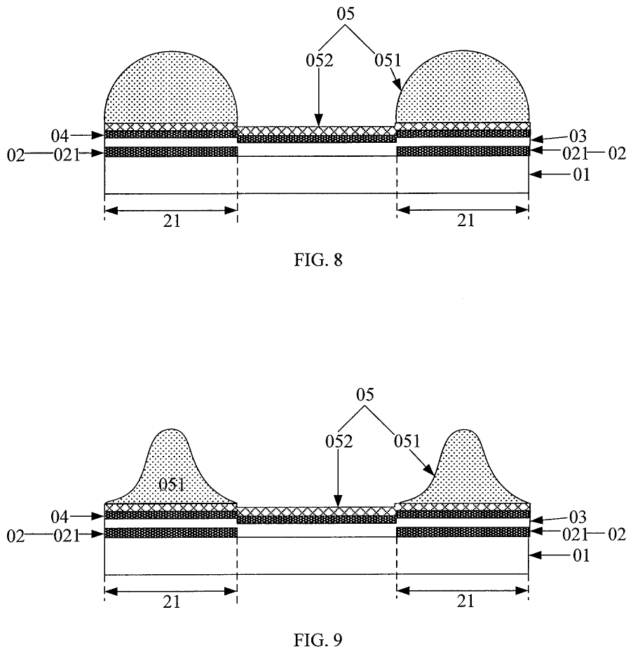

For example, FIG. 8 shows a display substrate obtained by adding a pad layer 052 to the display substrate shown in FIG. 1, and FIG. 9 shows a display substrate obtained by adding the pad layer 052 to the display substrate shown in FIG. 3. Referring to FIG. 8 or FIG. 9, the protrusion 051 may be arranged at a side of the pad layer 052 away from the base substrate 01. The orthographic projection of the protrusion 051 on the base substrate 01 is located within the orthographic projection of the pad layer 052 on the base substrate 01, and is different from the orthographic projection of the pad layer 052 on the base substrate 01. In addition, as an example in FIG. 8 and FIG. 9, the base substrate 01 is entirely covered by the pad layer 052. Alternatively, the base substrate 01 may be partially covered by the pad layer 052, which is not limited in the embodiment of the present disclosure.

The pad layer 052 may be made from the same material as the protrusion 051 and formed integrally with the protrusion 051. Alternatively, the pad layer 052 and the protrusion 051 may be separated by each other, which is not limited by the embodiment of the present disclosure.

When the shielding layer 05 includes a pad layer 052, the pad layer 052 and two adjacent protrusions 051 can form a receiving groove. The foreign matter particles on the protrusion 051 are able to slide from the protrusion 051 into the receiving groove. When the shielding layer 05 does not include a pad layer 052, the source and drain layer 04 and two adjacent protrusions 051 can form a receiving groove. The foreign matter particles on the protrusion 051 are able to slide from the protrusion 051 into the receiving groove.

The shielding layer 05 may have one protrusion 051 or a plurality of protrusions 051. When the shielding layer 05 has the plurality of protrusions 051, the minimum distance between any two adjacent protrusions 051 may be greater than or equal to a distance threshold x, where 2 μm≤x≤3 μm. For example, the minimum distance between any two adjacent protrusions 051 is 7 μm or 8 μm, etc.

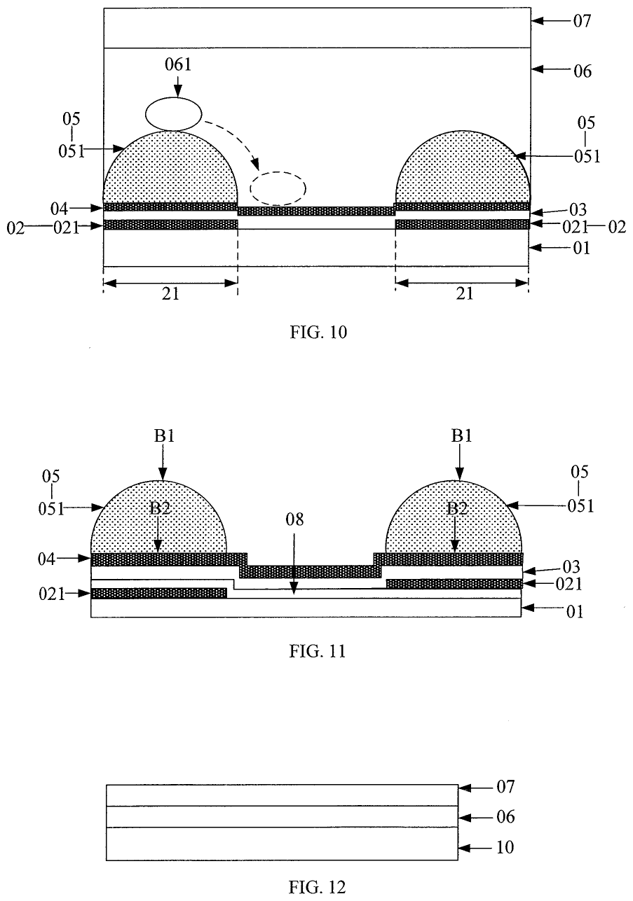

It should be noted that, referring to FIG. 10, the side of the display substrate where the shielding layer 05 is located is used to be bonded with the cover plate 07 through the encapsulant 06. Generally, the distance threshold x is equal to the diameter of the external tangent sphere of the foreign particle 061 in the encapsulant 06. When the minimum distance between any two adjacent protrusions 051 is greater than or equal to x, the foreign particle 061 can be accommodated between any two adjacent protrusions 051. In this case, the foreign particle 061 can completely fall within the space between the adjacent protrusions 051 and thus the pressure on the intersection of the gate layer 02 and the source and drain layer 04 is small, so that the probability that the foreign particles 061 are pressed to penetrate the gate layer 02 and the source and drain layer 04 is small. In some embodiments, the minimum distance between any two adjacent protrusions 051 may also be less than the distance threshold x, which is not limited by the embodiments of the present disclosure.

Further, in the above embodiment, a plurality of gate patterns 021 in the gate layer 02 are located in the same layer, as an example. Alternatively, the plurality of gate patterns 021 may also be located in different layers respectively. For example, by taking the display substrate shown in FIG. 1 as an example, on the basis of the display substrate shown in FIG. 1, the plurality of gate patterns 021 may also be located in different layers respectively. In this case, as shown in FIG. 11, the display substrate may further include a spacer insulating layer 08. Some of the plurality of gate patterns 021 are located on the side of the spacer insulating layer 08 that faces toward the base substrate 01, while others of the gate pattern 021 are located on the side of the spacer insulating layer 08 that faces away from the base substrate 01.

In summary, in the display substrate provided by the embodiment of the present disclosure, the side of the shielding layer that faces away from the base substrate has protrusions, and the orthographic projection of the protrusions on the base substrate overlaps with the target orthographic projection. When the display substrate and the cover plate are bonded by the encapsulant, it is difficult for the foreign particles in the encapsulant to stay on the protrusion, so it is difficult for the foreign particles to be pressed to penetrate the intersection of the source and drain layer and the gate layer. Therefore, the probability of short-circuiting between the source and drain layer and the gate layer can be reduced, thereby reducing the probability of dark lines appearing on the display panel during displaying images, and improving the quality of the display panel. Therefore, the technical effect of protecting the circuit (such as the backplate circuit on the driver integrated circuit end and the backplate circuit in the display area) on the backplate is realized.

FIG. 12 is a schematic view showing a structure of a display panel according to an embodiment of the present disclosure. As shown in FIG. 12, the display panel may include a cover plate 07, encapsulant 06, and a display substrate 10.

For example, the cover plate 07 may be a glass cover plate, or a cover plate made from other materials, such as a polyimide cover plate or the like. The display substrate 10 may be the display substrate provided by the embodiments of the present disclosure, such as the display substrate shown in any of FIG. 1 to FIG. 11. The side of the display substrate 10 on which the shielding layer is located is bonded to the cover plate 07 by the encapsulant 06. The display panel may be such as an OLED display panel, an LED display panel, or a liquid crystal display panel.

The embodiment of the present disclosure further provides a display device, which includes the display panel (as shown in FIG. 12) provided by the embodiment of the present disclosure. The display device may be any product or component having display function, such as such as electronic paper, mobile phones, tablet computers, televisions, displays, notebook computer, digital photo frames, navigators and the like.

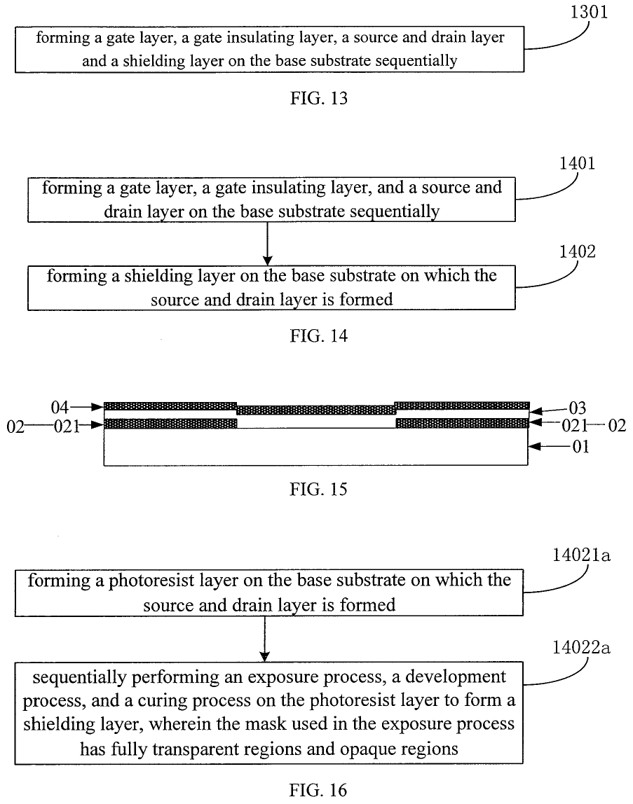

FIG. 13 is a flowchart of a method of manufacturing a display substrate according to an embodiment of the present disclosure. Referring to FIG. 13, the manufacturing method may include:

Step 1301: forming a gate layer, a gate insulating layer, a source and drain layer, and a shielding layer on the base substrate sequentially.

The side of the shielding layer that faces away from the base substrate has a protrusion. The orthographic projection of the protrusion on the base substrate overlaps with a target orthographic projection. The target orthographic projection includes: a portion of the orthographic projection of the gate layer on the base substrate that overlaps with the orthographic projection of the source and drain layer on the base substrate.

In summary, in the display substrate which is manufactured by the method provided by the embodiment of the present disclosure, the side of the shielding layer that faces away from the base substrate has protrusions, and the orthographic projection of the protrusions on the base substrate overlaps with the target orthographic projection. When the display substrate and the cover plate are bonded by the encapsulant, it is difficult for the foreign particles in the encapsulant to stay on the protrusion, so it is difficult for the foreign particles to be pressed to penetrate the intersection of the source and drain layer and the gate layer. Therefore, the probability of short-circuiting between the source and drain layer and the gate layer can be reduced, thereby reducing the probability of dark lines appearing on the display panel during displaying images, and improving the quality of the display panel. Therefore, the technical effect of protecting the circuit (such as the backplate circuit on the driver integrated circuit end and the backplate circuit in the display area) on the backplate is realized.

FIG. 14 is a flowchart of a method of manufacturing another display substrate according to an embodiment of the present disclosure. Referring to FIG. 14, the manufacturing method may include:

Step 1401: forming a gate layer, a gate insulating layer, and a source and drain layer on the base substrate sequentially.

For example, referring to FIG. 15, after the step 1401 is performed, the gate layer 02, the gate insulating layer 03, and the source and drain layer 04 are formed on the base substrate 01, and the gate layer 02 includes a plurality of gate patterns 021.

In addition, in the case where the display substrate further includes a spacer insulating layer, after forming some of the gate patterns in the gate layer in step 1401, the spacer insulating layer may be formed firstly and then the others of the gate patterns are formed.

Step 1402: forming a shielding layer on the base substrate on which the source and drain layer is formed.

For example, after step 1402 is performed, the display substrate as shown in any of FIG. 1 to FIG. 11 can be obtained. The step 1402 may be performed in a plurality of manners. Two manners will be described below as examples.

In a first manner, as shown in FIG. 16, the step 1402 may include: Step 14021a: forming a photoresist layer on the base substrate on which the source and drain layer is formed.

For example, as an example of the embodiment of the present disclosure, the photoresist layer is a positive photoresist layer (such as an ultraviolet positive photoresist layer that is sensitive to the ultraviolet light). Alternatively, the photoresist layer may also be a negative photoresist layer. The composition of the photoresist layer may include propylene glycol, methyl ether, acetate, benzyl alcohol, nitrogen oxides, and the like, which are not limited in the examples of the present disclosure.

Step 14022a: sequentially performing an exposure process, a development process, and a curing process on the photoresist layer to form a shielding layer, wherein the mask used in the exposure process has fully transparent regions and opaque regions.

When the photoresist layer is exposed to a light, the mask may be placed on the side of the photoresist layer that faces away from the base substrate, and the photoresist layer is exposed through the mask. The mask has fully transparent regions and opaque regions. The light transmittance of the fully transparent region is 100%, and the light transmittance of the opaque region is 0%. Due to the light shielding effect of the opaque region in the mask, the individual regions of the photoresist layer are exposed selectively and the exposure process is completed.

After the photoresist layer is exposed to a light, the photoresist layer may be developed. For example, if the photoresist layer is a positive photoresist layer, the exposed portion of the photoresist layer will be removed by chemical reaction; if the photoresist layer is a negative photoresist layer, the unexposed portion of the photoresist layer will be removed by chemical reaction.

Then, the portion of the photoresist layer that is left will be cured. During the curing process, the left portion of the photoresist layer forms a plurality of protrusions 051 as shown in FIG. 1 due to the surface tension of the photoresist.

It should be noted that, in the case where the shielding layer includes not only the protrusions but also the pad layer, if the of the pad layer and the protrusions are made from the same material, they may be formed in one go by adjusting the duration of the exposure in step 14022a. Alternatively, the pad layer and the protrusions may be formed in one go by replacing the mask used in step 14022a with a mask having an opaque region and a semi-transparent region.

If the pad layer and the protrusion are made from different materials respectively, a pad layer may be formed on the base substrate on which the source and drain layer is formed before the photoresist layer is formed in step 14021a. Then, in step 14021a, a photoresist layer may be formed on the base substrate on which the pad layer is formed, and the photoresist layer may be sequentially subjected to exposure processing, development processing, and curing processing to obtain the protrusions.

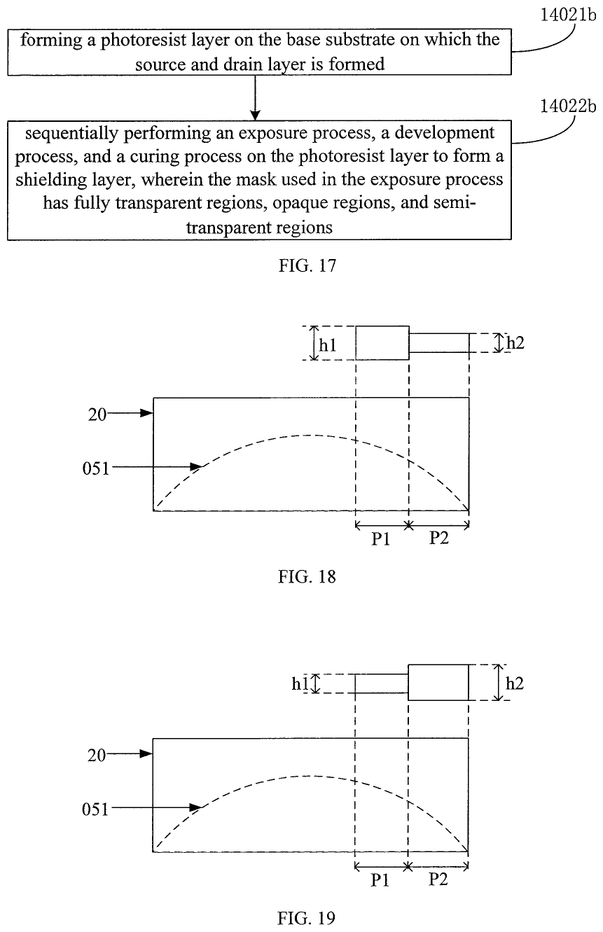

In a second manner, as shown in FIG. 17, the step 1402 may include:

Step 14021b: forming a photoresist layer on the base substrate on which the source and drain layer is formed.

Step 14022b: sequentially performing an exposure process, a development process, and a curing process on the photoresist layer to form a shielding layer, wherein the mask used in the exposure process has fully transparent regions, opaque regions, and semi-transparent regions.

It should be noted that the second manner differs from the first manner in that the mask used in the exposure processing is different. In the first manner, the mask used in the exposure processing includes the fully transparent regions and the opaque regions only; while in the second manner, the mask used in the exposure processing further includes semi-transparent regions in addition to the fully transparent regions and the opaque regions. The light transmittance of the fully transparent region is 100%, the light transmittance of the opaque region is 0%, and the light transmittance of the semi-transparent region is greater than 0% and less than 100%. Moreover, the semi-transparent regions of the mask may have one or more light transmittances.

When the photoresist layer is a positive photoresist layer, the exposed portion of the photoresist layer can be removed during the development processing. Therefore, based on the thickness of the protrusion to be formed, the light transmittance of the corresponding position in the mask can be determined. Moreover, the light transmittances of individual regions in the mask are positively correlated with the thickness of each corresponding region generally. Therefore, based on the thickness of the protrusion to be formed, the thickness of the corresponding position in the mask can be determined. By way of example, as shown in FIG. 18, it is assumed that the photoresist layer 20 is used to form the protrusion 051. The protrusion 051 to be formed has a larger thickness at the region P2 than at the region P1. Therefore, when the photoresist layer 20 is exposed to a light, it is required that the exposure intensity at the region P1 is smaller than the exposure intensity at the region P2, such that the exposed portion in the region P1 is smaller than the exposed portion in the region P2. Accordingly, the thickness h1 of the portion of the mask corresponding to the region P1 is larger, and the transmittance of the portion of the mask corresponding to the region P1 is smaller; while the thickness h2 of the portion of the mask corresponding to the region P2 is smaller, and the transmittance of the portion of the mask corresponding to the region P2 is larger.

When the photoresist layer is a negative photoresist layer, the exposed portion of the photoresist layer would be left during development processing, while the unexposed portion would be removed during development processing. Therefore, based on the thickness of the protrusion to be formed, the light transmittance of the corresponding position in the mask can be determined. Moreover, the light transmittances of individual regions in the mask are positively correlated with the thickness of each corresponding region generally. Therefore, based on the thickness of the protrusion to be formed, the thickness of the corresponding position in the mask can be determined. By way of example, as shown in FIG. 19, it is assumed that the photoresist layer 20 is used to form the protrusion 051. The protrusion 051 to be formed has a larger thickness at the region P1 than at the region P2. Therefore, when the photoresist layer 20 is exposed to a light, it is required that the exposure intensity at the region P1 is larger than the exposure intensity at the region P2, such that the exposed portion in the region P1 is larger than the exposed portion in the region P2. Accordingly, the thickness h1 of the portion of the mask corresponding to the region P1 is arranged smaller, and the transmittance of the portion of the mask corresponding to the region P1 is arranged larger; while the thickness h2 of the portion of the mask corresponding to the region P2 is larger, and the transmittance of the portion of the mask corresponding to the region P2 is smaller.

In summary, in the display substrate which is manufactured by the method provided by the embodiment of the present disclosure, the side of the shielding layer that faces away from the base substrate has protrusions, and the orthographic projection of the protrusions on the base substrate overlaps with the target orthographic projection. When the display substrate and the cover plate are bonded by the encapsulant, it is difficult for the foreign particles in the encapsulant to stay on the protrusion, so it is difficult for the foreign particles to be pressed to penetrate the intersection of the source and drain layer and the gate layer. Therefore, the probability of short-circuiting between the source and drain layer and the gate layer can be reduced, thereby reducing the probability of dark lines appearing on the display panel during displaying images, and improving the quality of the display panel. Therefore, the technical effect of protecting the circuit (such as the backplate circuit on the driver integrated circuit end and the backplate circuit in the display area) on the backplate is realized.

It is noted that, in the drawings, the dimensions of layers and areas may be exaggerated for clarity of the illustration. It is appreciated that when an element or layer is referred to as being “on” another element or layer, it may be directly on another element or layer, or an intermediate layer may be present therebetween. In addition, it is understood that when an element or layer is referred to as being “under” another element or layer, it may be directly under another element or layer, or at least one intermediate layer may be present therebetween. In addition, it is understood that when a layer or element is referred to as being “between” two layers or two elements, it may be the only layer or element between two layers or two elements, or more than one intermediate layer or element may also be present therebetween. Like reference numerals refer to like elements throughout the specification.

In the present disclosure, the terms “first”, “second”, “third”, and “fourth” are used for descriptive purposes only and are not to be considered as indicating or implying relative importance. The term “plurality” refers to two or more, unless specifically defined otherwise.

It should be noted that the method embodiments and corresponding display substrate embodiments according the present disclosure may refer to each other, which is not limited by the embodiment of the present disclosure. The sequence of the steps of the method embodiments provided by the embodiments of the present disclosure can be appropriately adjusted, and the steps can also be correspondingly increased or decreased as required. Any person skilled in the art can readily conceive modification or substitutions within the technical scope of the disclosure, which should fall within the scope of protection of the present disclosure and thus is not repeated herein.

Other embodiments of the present disclosure will be readily apparent to those skilled in the art upon consideration of the specification and practice of the invention disclosed herein. The present disclosure is intended to cover any variations, uses or adaptations of the present disclosure that follow the general principles of the present disclosure and include the common knowledge or conventional techniques not disclosed in this disclosure. The specification and embodiments are to be regarded as illustrative only, and the reasonable scope and spirit of the disclosure is indicated by the appended claims.

It is appreciated that the present disclosure is not limited to the precise structure that has been described above and shown in the drawings, and various modifications and changes can be made without departing from the scope thereof. The scope of the present disclosure is limited only by the appended claims.

1. A display substrate, wherein the display substrate comprises a base substrate, a gate layer, a gate insulating layer, a source and drain layer, and a shielding layer;
the gate layer, the gate insulating layer, the source and drain layer and the shielding layer are arranged sequentially in a direction away from the base substrate;
wherein, a side of the shielding layer that faces away from the base substrate has a protrusion, and an orthographic projection of the protrusion on the base substrate overlaps with a target orthographic projection; and the target orthographic projection comprises: a portion of an orthographic projection of the gate layer on the base substrate overlaps with an orthographic projection of the source and drain layer on the base substrate.

2. The display substrate according to claim 1, wherein a surface of the protrusion that faces away from the base substrate, comprises a convex surface.

3. The display substrate according to claim 2, wherein the convex surface comprises a curved convex surface.

4. The display substrate according to claim 3, wherein a generatrix of the curved convex surface has a semicircle shape.

5. The display substrate according to claim 1, wherein the protrusion has one or more side surfaces which connect a surface of the protrusion that faces towards the base substrate with a surface of the protrusion that faces away from the base substrate, and the one or more side surfaces of the protrusion comprise a concave surface.

6. The display substrate according to claim 5, wherein the concave surface comprises a curved concave surface.

7. The display substrate according to claim 1, wherein a surface of the protrusion that faces away from the base substrate and a surface of the protrusion that faces towards the base substrate have one or more shared edges.

8. The display substrate according to claim 7, wherein the surface of the protrusion that faces away from the base substrate and the surface of the protrusion that faces towards the base substrate have two shared edges which extend in the same direction.

9. The display substrate according to claim 1, wherein the protrusion is strip-shaped, and a lengthwise direction of the protrusion is parallel to the base substrate.

10. The display substrate according to claim 9, wherein a width of the orthographic projection of the protrusion on the base substrate is greater than or equal to 2.4 μm.

11. The display substrate according to claim 1, wherein a material of the protrusion comprises photoresist.

12. The display substrate according to claim 1, wherein the shielding layer comprises a plurality of the protrusions, and there is a space between orthographic projections of any two adjacent protrusions on the base substrate.

13. The display substrate according to claim 12, wherein a minimum distance between any two adjacent protrusions is greater than or equal to a distance threshold x, where the distance threshold is in a range between 2 μm and 3 μm.

14. The display substrate according to claim 1, wherein the shielding layer comprises a pad layer and the protrusion;
the protrusion is arranged at a side of the pad layer away from the base substrate, and the orthographic projection of the protrusion on the base substrate is located within an orthographic projection of the pad layer on the base substrate and is different from the orthographic projection of the pad layer on the base substrate.

15. The display substrate according to claim 1, wherein the orthographic projection of the gate layer on the base substrate is located within an orthographic projection of all the protrusion in the shielding layer on the base substrate.

16. The display substrate according to claim 15, wherein, the shielding layer comprises a plurality of the protrusions, and the gate layer comprises a plurality of gate patterns;
there is a space between orthographic projections of any two adjacent protrusions on the base substrate, and an orthographic projection of each of the gate patterns on the base substrate is located within an orthographic projection of its corresponding protrusion on the base substrate.

17. The display substrate according to claim 1, wherein the gate layer comprises a plurality of gate patterns, and the display substrate further comprises a spacer insulating layer;
some of the plurality of gate patterns are located on a side of the spacer insulating layer that faces towards the base substrate, while others of the plurality of gate patterns are located on a side of the spacer insulating layer that faces away from the base substrate.

18. A display panel, comprising a cover plate, encapsulant, and the display substrate according to claim 1, wherein a side of the display substrate on which the shielding layer is located is bonded to the cover plate by the encapsulant.

19. A display device, wherein the display device comprises the display panel according to claim 18.

20. A method of manufacturing a display substrate, the method comprising:
forming a gate layer, a gate insulating layer, a source and drain layer, and a shielding layer on a base substrate sequentially;
wherein, a side of the shielding layer that faces away from the base substrate has a protrusion, and an orthographic projection of the protrusion on the base substrate overlaps with a target orthographic projection; the target orthographic projection comprises: a portion of an orthographic projection of the gate layer on the base substrate that overlaps with an orthographic projection of the source and drain layer on the base substrate.
